(19) United States
(12) Patent Application Publication
(10) Pub. No.: US 2025/0201485 A1
(43) Pub. Date: Jun. 19, 2025

(54) VERTICALLY EMBEDDED PRE-FORMED DEEP TRENCH CAPACITOR MODULES

(71) Applicant: Intel Corporation, Santa Clara, CA (US)

(72) Inventors: Hiroki Tanaka, Gilbert, AZ (US); Srinivas Pietambaram, Chandler, AZ (US); Robert May, Chandler, AZ (US); Kristof Darmawikarta, Chandler, AZ (US); Aleksandar Aleksov, Chandler, AZ (US); Bohan Shan, Chandler, AZ (US); Gang Duan, Chandler, AZ (US)

(73) Assignee: Intel Corporation, Santa Clara, CA (US)

(21) Appl. No.: 18/540,683

(22) Filed: Dec. 14, 2023

(51) Int. Cl. H01G 4/38; H01G 4/224; H01L 21/48; H01L 23/498; H01L 25/16

(52) U.S. Cl. CPC H01G 4/385; H01G 4/224; H01L 21/4846; H01L 23/498; H01L 25/165

(57) ABSTRACT

Apparatuses, capacitor modules, assemblies, and techniques related to package substrate embedded capacitors are described. A capacitor module is formed by fabricating capacitor structures along a surface of one or more substrates, cutting the capacitor structures from the one or more substrates and stacking the resultant capacitor structures and substrates into a capacitor module. The capacitor module is then vertically embedded in a package substrate or core.

### BACKGROUND

Higher performance, lower cost, increased miniaturization, and greater packaging density of integrated circuits within integrated circuit devices are ongoing goals of the electronics industry. As these goals are achieved, integrating capacitors into package assemblies continues to be an area of interest. For example, capacitors may be embedded in package substrates. However, current capacitors have limitations in terms of overall device thickness and others. Such limited device thicknesses cause difficulties in assembly when being installed in an opening that has a greater thickness than the device thickness, including x-, y-, z-misalignment, rotational shift, tilting, encapsulation thickness variations, and others.

Next generation products require capacitor devices to be integrated into the system efficiently and with a wide range of available device parameters and characteristics. However, current capacitor implementations do not meet these needs. It is with respect to these and other considerations that the present improvements have been needed. Such improvements may become critical as the desire to deploy advanced package assemblies in a variety of products becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for forming a capacitor module including a number of stacked substrates each including a number of capacitor structures;

FIGS. 2, 3A, 4, 5, 6, 7, 8, 9, 10, 11 and 12 provide top-down views and cross-sectional views of capacitor structures and capacitor modules evolving as the methods of FIG. 1 are practiced;

FIG. 3B provides a top-down view illustrating multiple capacitor modules formed on a single substrate;

FIGS. 3C, 3D, 3E, and 3F provide top-down views illustrating exemplary trench and capacitor shapes;

FIG. 13 is a flow diagram illustrating methods for assembling a package including a vertical capacitor module including a number of stacked substrates each including a number of capacitor structures embedded in a package substrate;

FIGS. 14, 15, 16, 17, 18, 19, 20, 21, 22, 23, 24, 25, and 26 illustrate cross-sectional side views of package structures evolving as the methods of FIG. 13 are practiced;

FIG. 27 illustrates an example microelectronic device assembly including a vertically embedded 2D pre-formed capacitor module;

FIG. 28 illustrates exemplary systems deploying a vertically embedded 2D pre-formed capacitor module; and

FIG. 29 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “predominantly” indicates not less than 50% of a particular material or component while the term “substantially pure” indicates not less than 99% of the particular material or component. Unless otherwise indicated, such material percentages are based on atomic percentage. As used herein, the terms “monolithic”, “monolithically integrated”, and similar terms indicate the components of the monolithic overall structure form a indivisible whole not reasonably capable of being separated.

The term “package” generally refers to a self-contained carrier of one or more dies, where the dies are attached to the package substrate, and may be encapsulated for protection, with integrated or wire-boned interconnects between the dies and leads, pins or bumps located on the external portions of the package substrate. The package may contain a single die, or multiple dies, providing a specific function. The package is usually mounted on a printed circuit board for interconnection with other packaged integrated circuits and discrete components, forming a larger circuit. Here, the term “dielectric” and the term “insulative and any similar term generally refers to any number of non-electrically conductive materials that make up the structure of a package substrate. For purposes of this disclosure, dielectric material may be incorporated into an integrated circuit package as layers of laminate film or as a resin molded over integrated circuit dies mounted on the substrate. Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric. Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together. Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

Apparatuses, systems, capacitor modules, and techniques are described herein related to vertically aligned preformed capacitor modules that may be embedded in a package substrate.

As discussed, it is desirable to efficiently provide capacitors having a wide range of capabilities in a package assembly. Currently, embedded capacitors such as deep trench capacitors (DTCs) may be fabricated in a silicon wafer such that the length of the capacitor extends orthogonal to the working surface of the silicon wafer substrate. Such DTCs then have a practical thickness limitation of about 650 μm, which is the maximum thickness of a silicon wafer. When the DTCs are then embedded into a cavity that extends into or through a relatively thick package substrate or substrate core, which has a thickness of about 1.4 mm, there is process difficulty with respect to x-, y-, z-misalignment, rotational shift, tilting, encapsulation thickness variations post DTC attachment, encapsulation processing inside of the cavity, and others. For example, the DTC device being embedded into the substrate core is much thinner than the core cavity depth, which causes the discussed challenges. In addition, challenges arise with respect to the limitation of surface area for capacitance when the capacitors are fabricated in a silicon wafer such that the length of the capacitor extends orthogonal to the working surface of the silicon wafer substrate.

In some embodiments, such difficulties are resolved or mitigated by forming a capacitor module such that the capacitors are formed along the surface of a substrate (i.e., not with a length of the capacitor extending along a substrate surface instead orthogonal to the working surface of the fer substrate). By forming the capacitors with the length of the capacitor extending planar to the working surface of the substrate, the capacitor length is not limited by the depth of the substrate but instead by its lateral dimensions, which are much larger. After forming the capacitors within openings that run along the surface(s) of the substrate(s), for example, the substrate and capacitor structures are cut substantially orthogonal to the length of the capacitors, for example, which provides contact access to the capacitor structures at an edge of the substrate created by the cut. The formed capacitor structures include any number of capacitors having a length along a surface of the substrate and access to the capacitors for later contact at an edge. These capacitor structures may then be stacked and, for example, glued at their surfaces such that the edges are substantial coplanar and allow electrical access to the capacitor structures. This provides a capacitor module that has insulated capacitors of a length not limited by the depth of the substrate used to form it as well as electrical access at a surface formed by the combined edges.

This capacitor module, having any number of capacitors and substrates, may then be embedded within an opening or cavity within a package substrate such as an organic package substrate or organic cure. Due to the characteristics of manufacture, the capacitor module may have any suitable thickness (as defined by the cut or cuts used to form it) such as, for example, a thickness matching the depth of the opening or cavity or a thickness that is conducive to inserting the capacitor module within the opening or cavity. Thereby, the discussed to x-,y-,z-misalignment, rotational shift, tilting, encapsulation thickness variations post attachment, encapsulation processing inside of the cavity, and others are mitigated or resolved. Furthermore, by freeing the capacitors from the constraints of being formed in a deep trench manner orthogonal to the substrate surface, much longer capacitors may be formed, other materials may be deployed, and so on. Notably, using vertically embedded 2D preformed DTC patches or modules as discussed herein may make up for the total capacitor thickness that can be matched to the discussed core opening thickness. In this way, more accurate capacitor placement may be made. Furthermore, since capacitors can be pre-made on a substrate such as a glass panel, there is essentially no limitation of surface area that may be used to increase capacitance of the capacitors. This offers a wide range of capacitor characteristics and flexibility. Other advantages will be evident based on the present disclosure.

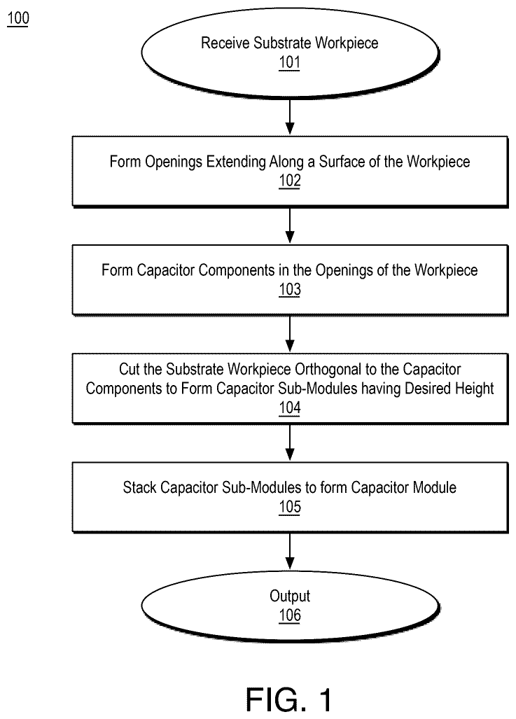

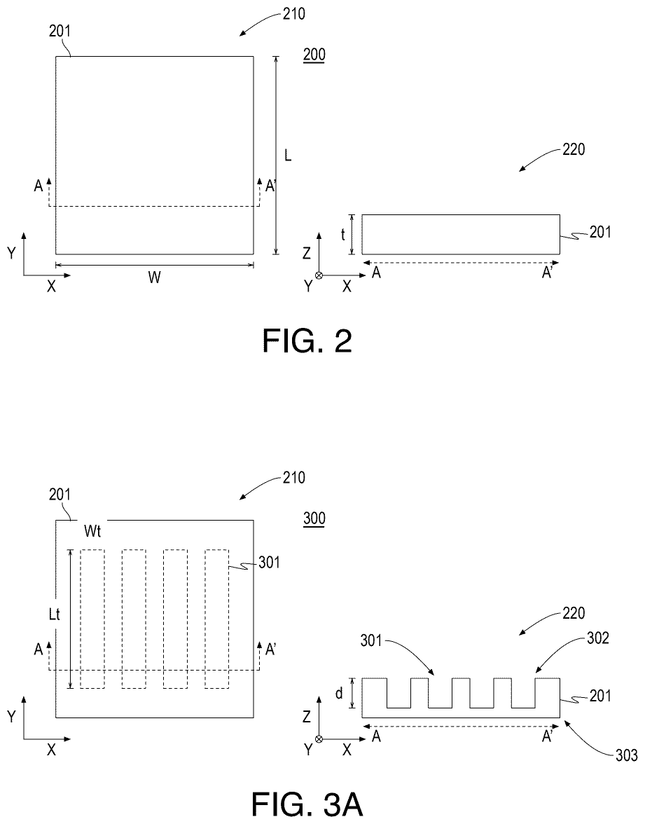

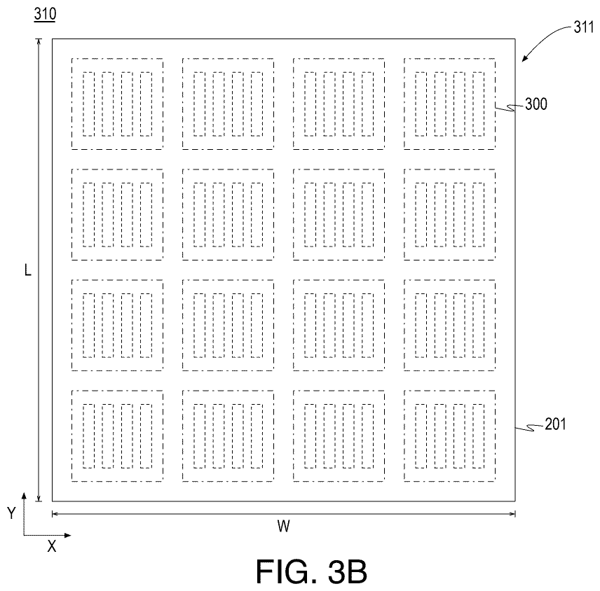

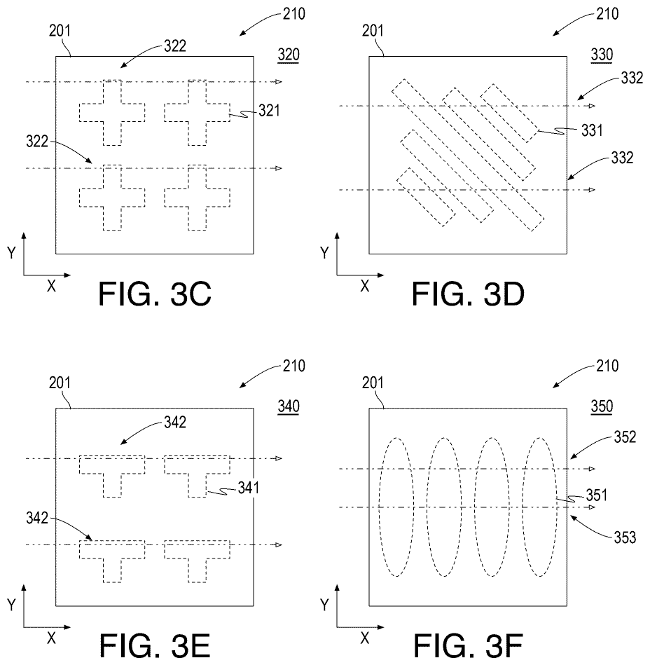

FIG. 1 is a flow diagram illustrating methods 100 for forming a capacitor module including a number of stacked substrates each including a number of capacitor structures, arranged in accordance with some embodiments of the disclosure. Methods 100 may be practiced, for example, to fabricate any capacitor structures, capacitor modules, apparatuses, or systems discussed herein. FIGS. 2, 3A, 4, 5, 6, 7, 8, 9, 10, 11 and 12 provide top-down views and cross-sectional views of capacitor structures and capacitor modules evolving as methods 100 are practiced, arranged in accordance with some embodiments of the disclosure. FIG. 3B provides a top-down view illustrating multiple capacitor modules 310 formed on a single substrate, arranged in accordance with some embodiments of the disclosure. FIGS. 3C, 3D, 3E, and 3F provide top-down views illustrating exemplary trench and capacitor shapes, arranged in accordance with some embodiments of the disclosure. For example, methods 100 illustrate a process flow for fabricating 2D pre-formed capacitor patches or modules for later use in package assemblies.

Methods 100 begin at input operation 101, where a workpiece including a substrate on which capacitors may be formed is received. The workpiece includes any suitable substrate material or material layers on which capacitor structures may be formed. The substrate may include any materials discussed herein and may have any suitable format or architecture. In some embodiments, the substrate is a glass panel such as a 500 mm×510 mm glass carrier panel. In some embodiments, the substrate is a silicon wafer such as a 300 mm silicon wafer.

FIG. 2 provides a top-down view 210 and a cross-sectional side view 220 of a capacitor structure 200 illustrating a received substrate 201. For example, cross-sectional side view 220 is taken at the A-A′ plane as shown in top-down view 210. In the following, top-down view 210 and cross-sectional side view 220 are maintained as methods 100 are practiced. In the illustrated example, a portion of substrate 201 having a rectangular form factor is illustrated. Substrate 201 may have a length L (see FIG. 3B), a width W (see FIG. 3B), and a thickness t (shown in FIG. 2). However, substrate 201 may have any suitable form factor. FIG. 3B herein below illustrates an example of capacitor structure 200 being formed on substrate 201 in expanded view.

In some embodiments, substrate 201 is a glass substrate such as a layer of glass (e.g., a glass core). In some embodiments, substrate 201 is an amorphous solid glass layer. In some embodiments, substrate 201 is a layer of glass, which, for example, is one of aluminosilicate, borosilicate, alumino-borosilicate, silica, and fused silica. The layer of glass may include one or more of additives including Al₂O₃, B₂O₃, MgO, CaO, SrO, BaO, SnO₂, Na₂O, K₂O, P₂O₃, ZrO₂, Li₂O, Ti, or Zn. For example, the layer of glass may include an additive including one or more of aluminum, boron, magnesium, calcium, strontium, barium, tin, sodium, potassium, phosphorous, zirconium, lithium, titanium, or zinc. In some embodiments, the layer of glass may include silicon and oxygen and one or more of aluminum, boron, magnesium, calcium, strontium, barium, tin, sodium, potassium, phosphorous, zirconium, lithium, titanium, and zinc. In some embodiments, the layer of glass includes at least 23 percent silicon and at least 26 percent oxygen by weight, and further includes at least 5 percent aluminum by weight. In some embodiments, the layer of glass is rectangular in shape in plan view. However, other shapes may be used. In some embodiments, substrate 201 is absent any organic adhesive or other organic material. In some embodiments, substrate 201 has a thickness t in the range of 50 microns to 1.4 mm (i.e., in the z-dimension). In some embodiments, substrate 201 has a length L (see FIG. 3B) in the range of about 500 mm to 600 mm and a width W (see FIG. 3B) in the range of about 500 mm to 600 mm. In some embodiments, substrate 201 is a 500 mm×510 mm glass panel. In some embodiments, substrate is a multi-layer glass substrate. In some embodiments, substrate 201 is a single crystal silicon wafer. However, other substrate materials such as polycrystalline silicon and silicon on insulator (SOI) may be used. In some embodiments, substrate 201 is an inorganic substrate or material. As used herein, the term inorganic material indicates materials not having carbon as a foundational component or materials not having carbon-hydrogen bonds.

Returning to FIG. 1, processing continues at operation 102, where a trench opening is formed along a surface of the workpiece or substrate received at operation 102. The trench opening may be formed in the surface of the workpiece or substrate using any suitable technique or techniques. In some embodiments, the trench openings are formed using patterning and etch techniques. However, other techniques such as laser scribing, mechanical scribing, or the like may be deployed.

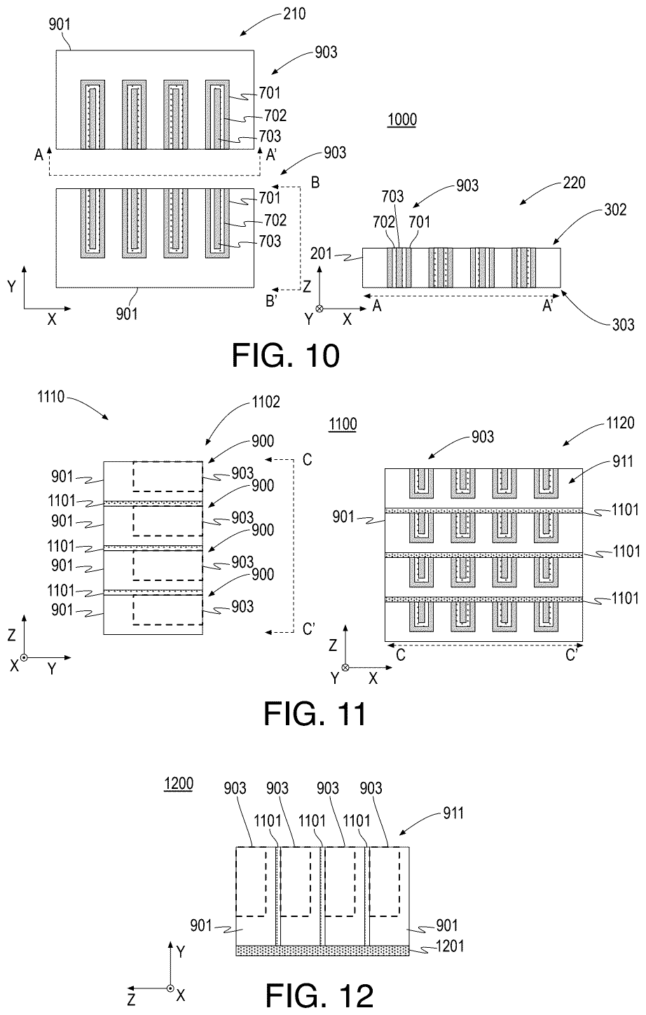

FIG. 3A illustrates a capacitor structure 300 similar to capacitor structure 200 after forming openings 301 in a surface 302 of substrate 201. As shown, surface 302 is a top, front, or working surface of substrate 201 and is opposite surface 303 of substrate 201. Surface 303 may be characterized as a backside surface. As discussed, in some embodiments, openings 301 are formed using patterning and etch techniques. Openings 301 extend along a length L of surface 302 of substrate 201 such that length L is in the x-y plane and is orthogonal to the depth of substrate 201. Openings 301 may also be characterized as trench openings, trenches, or the like. In some embodiments, openings 301 have a U-shaped cross-sectional profile as illustrated in FIG. 3A. In other embodiments, openings 301 have a V-shaped cross-sectional profile. In some embodiments, openings 301 extend from surface 302 to surface 303 as illustrated in FIG. 10 herein below.

Openings 301 may have any suitable length Lt, width Wt, and depth d. In some embodiments, length Lt is longer than a desired capacitor structure length such that capacitor structures formed in openings 301 are later cut down to the desired capacitor structure length. The desired capacitor structure length (less than Lt), width Wt, and depth d may be determined based on the characteristics of the capacitor being fabricated, the materials deployed, and so on. An advantage of the current techniques is that very long capacitor structure lengths may be fabricated for use in a vertical orientation as discussed further herein below. In some embodiments, the width Wt and depth d of openings 301 are in the range of about 5 to 100 um. Other dimensions may be used. Although illustrated with multiple parallel openings 301 of the same size, any desired shape and patterns may be deployed in capacitor structure 300, as illustrated further herein below.

FIG. 3B provides a top-down view illustrating multiple capacitor modules 311 formed on substrate 201 in an expanded view. FIG. 3B illustrates the length L and width W of substrate 201. In some embodiments, substrate 201 has a length L in the range of about 500 mm to 600 mm and a width W in the range of about 500 mm to 600 mm. In some embodiments, substrate 201 is a 500 mm×510 mm glass panel. FIG. 3B illustrates that a number of capacitor structures 300 (and corresponding capacitor structure as they evolve) may be fabricated on a single substrate 201, with the capacitor structures then being segmented from substrate 201 for deployment. Furthermore, FIG. 3B illustrates the capacitor structure size is only limited by the lateral dimensions of substrate 201, rather than the depth of substrate 201. Thereby, the capacitor structures size may be changed to meet nearly any design that is desired without practical limitation. For example, capacitor structures having a length Lc (see FIG. 9) in the 2 mm to 4 mm range may be fabricated on substrate 201, as well as capacitor structures having a length Lc greater than 4 mm up to the nearly the length L and width W of substrate 201. This capability in terms of capacitor size and flexibility is an important advantage of the discussed techniques.

FIG. 3C provides top-down views illustrating an exemplary capacitor structure 320 having a cross trench shape 321 for the capacitor structures discussed herein. For example, in the x-y plane (e.g., orthogonal to a vertical deployment discussed herein below), capacitor structures 300 (and corresponding capacitor structure as they evolve) may have any suitable shape. Again, the shaping of the capacitor structures is without limitation to the processing typically deployed along the depth of substrate 201. Instead, the discussed patterning may form cross trench shapes 321 or other suitable shapes for performance enhancement of the capacitor structures. FIG. 3D provides top-down views illustrating an exemplary capacitor structure 330 having a diagonal line trench shape 331 for the capacitor structures discussed herein. For example, diagonal line trench shape 331 may deploy diagonal lines or diagonal trenches at an angle with respect to a later cut to expose capacitor structures for inclusion in a package. FIG. 3E provides top-down views illustrating an exemplary capacitor structure 340 having a T-shape trench shape 341 for the capacitor structures discussed herein. FIG. 3F provides top-down views illustrating an exemplary capacitor structure 350 having an oval trench shape 351 for the capacitor structures discussed herein.

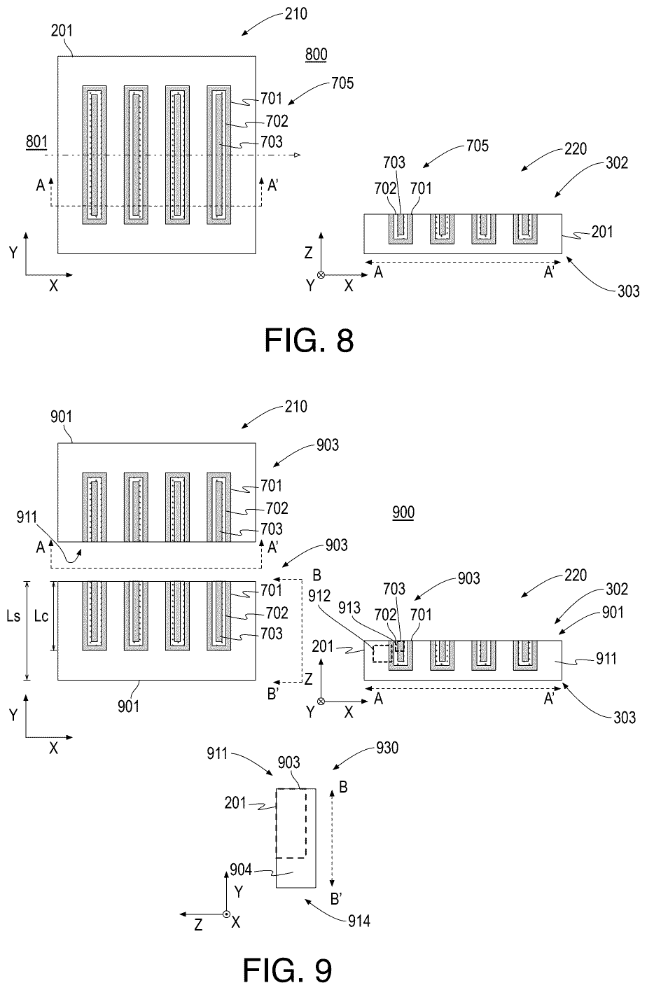

With reference now to FIGS. 8 and 9, capacitor structures will be segmented or cut for inclusion in a capacitor module. It is noted that the segmentation or cut may be made at any position of cross trench shape 321, diagonal line trench shape 331, T-shape trench shape 341, and oval trench shape 351 such as segmentation operation 801 (refer to FIG. 8) or cut in the x-z plane. In the context of cross trench shape 321 (see FIG. 3C) the segmentation may be made at the top of cross shape (i.e., at or near a top position 322 in the y-dimension) such that the stacked capacitor structure has a cross shape in the x-y plane). In the context of diagonal line trench shape 331 (see FIG. 3D) the segmentation may be made positions 332 to produce a stacked capacitor structure having diagonal lines in the x-y plane). In the context of T-shape trench shape 341 (see FIG. 3E) the segmentation may be made at the top of the T shape (i.e., at or near a top position 342 in the y-dimension) or at a bottom of the T shape (not shown) such that the stacked capacitor structure has a cross shape in the x-y plane). In the context of oval trench shape 351 (see FIG. 3F) the segmentation may be made at any position 352 of the oval shape (e.g., at or near a top position 352 in the y-dimension or near a mid-point 353) such that the stacked capacitor structure has a cross shape in the x-y plane). Other shapes and cuts may be used.

Returning to FIG. 1, processing continues at operation 103, where capacitor structures are formed in the trench openings formed at operation 102. In some embodiments, a first electrode metal layer is formed within the trench openings, a capacitor dielectric layer is formed on the first electrode metal layer, and a second electrode metal layer is formed on the capacitor dielectric layer. After such material deposition, planarization may be performed to form the capacitor structures such that each of the capacitor structures has a first surface conformal to the trench openings and a second surface that is substantially coplanar with the substate surface. The materials may be deposited using any suitable technique or techniques such as plating techniques, chemical vapor deposition techniques, atomic layer deposition techniques, and the like.

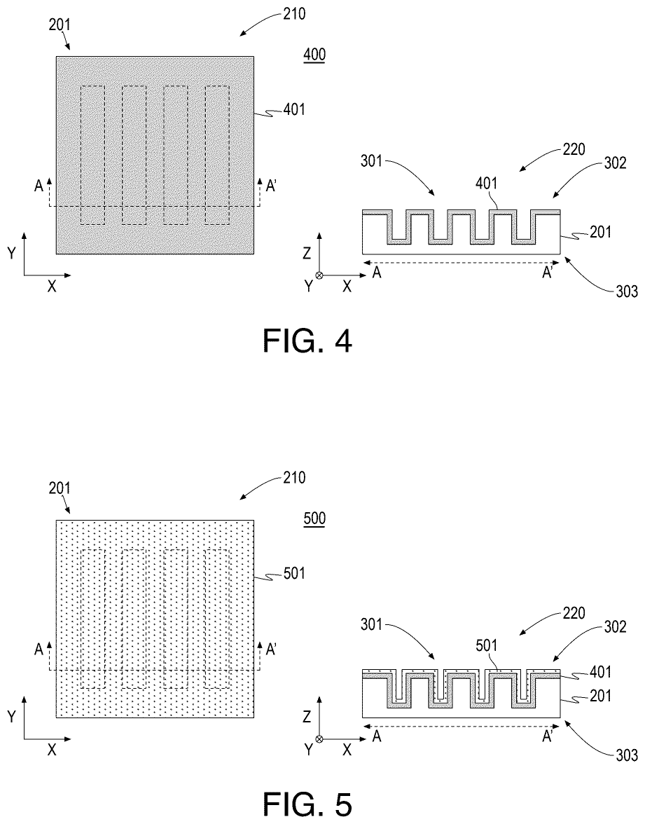

FIG. 4 illustrates a capacitor structure 400 similar to capacitor structure 300 after forming a conformal metal electrode layer 401 on surface 303 and within openings 301 of substrate 201. Although illustrated with respect to substantially linear shapes, capacitor structures of any shapes discussed herein may be formed. Conformal metal electrode layer 401 may be formed using any suitable technique or techniques discussed above and conformal metal electrode layer 401 may have any suitable thickness such as thickness in the range of 500 nm to 1 um. Other thicknesses may be used. Conformal metal electrode layer 401 may include any suitable conductive material or materials such as a metal or metals. Conformal metal electrode layer 401 may be a single layer or multilayer conductive film. In some embodiments, conformal metal electrode layer 401 is or includes titanium nitride (TiN, e.g., titanium and nitrogen), tungsten (W), tantalum nitride (TaN, e.g., tantalum and nitrogen), ruthenium (Ru), iridium (Ir), aluminum (Al), copper (Cu), titanium (Ti), cobalt (Co), chromium (Cr), molybdenum (Mo), nickel (Ni), gold (Au), or platinum (Pt).

FIG. 5 illustrates a capacitor structure 500 similar to capacitor structure 400 after forming a conformal capacitor dielectric layer 501 on conformal metal electrode layer 401 and over surface 302 and within openings 301 of substrate 201. Conformal capacitor dielectric layer 501 may be formed using any suitable technique or techniques discussed above and conformal capacitor dielectric layer 501 may have any suitable thickness such as thickness in the range of 500 nm to 1 um. Conformal capacitor dielectric layer 501 may include any suitable insulative material. Conformal capacitor dielectric layer 501 may be a single layer or multilayer dielectric including any suitable dielectric material(s) such as titanium oxide, zirconium oxide, aluminum oxide, hafnium oxide, silicon carbide, gallium nitride, silicon oxide, strontium titanate, barium titanate, strontium barium titanate, tantalum oxide, or combinations thereof optionally doped with oxygen or nitrogen. Other material systems inclusive of ferroelectric capacitor materials may be used.

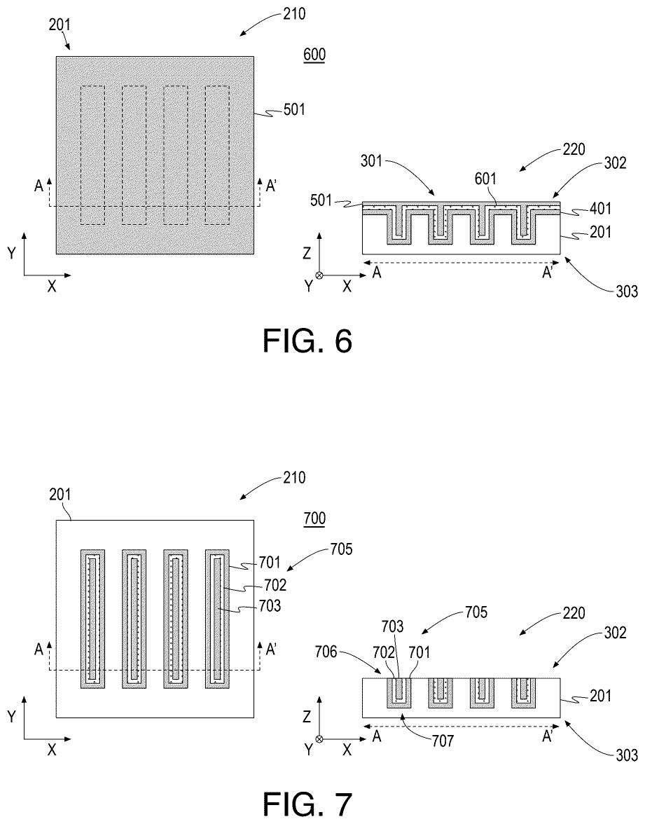

FIG. 6 illustrates a capacitor structure 600 similar to capacitor structure 500 after forming a metal electrode layer 601 on conformal capacitor dielectric layer 501 and over surface 302and within openings 301 of substrate 201. Metal electrode layer 601 may be formed using any suitable technique or techniques discussed above and metal electrode layer 601 may have any suitable thickness such as thickness in the range of 500 nm to 1 μm. In some embodiments, metal electrode layer 601 is formed of multiple layers or materials such as a conformal metal layer followed by a metal fill. For example, metal electrode layer 601 may be formed by metal deposition followed by a metal plating operation. Metal electrode layer 601 may include any suitable conductive material or materials such as a metal or metals including but not limited to those discussed with respect to conformal capacitor dielectric layer 501. For example, metal electrode layer 601 may include one or more of titanium nitride (TiN, e.g., titanium and nitrogen), tungsten (W), tantalum nitride (TaN, e.g., tantalum and nitrogen), ruthenium (Ru), iridium (Ir), aluminum (Al), copper (Cu), titanium (Ti), cobalt (Co), chromium (Cr), molybdenum (Mo), nickel (Ni), gold (Au), or platinum (Pt).

FIG. 7 illustrates a capacitor structure 700 similar to capacitor structure 600 after planarization processing removes excess materials of conformal metal electrode layer 401, conformal capacitor dielectric layer 501 from surface 302 of substrate 201 and from over openings 301 to form capacitor components 705 each including a first electrode layer 701, a dielectric layer 702, and a second electrode layer 703. The planarization processing may be performed using any suitable technique or techniques and provides planar capacitor surfaces 706 of capacitor components 705 that are substantially coplanar with surface 302 of substrate 201 (i.e., in the x-y plane). After planarization, each of capacitor components 705 includes planar capacitor surface 706 (i.e., substantially planar in the x-y plane) and conformal capacitor surface 707, which is substantially conformal to trench 301. Thereby, in cross-section of the x-z plane, each of capacitor components 705 may have a shape that has a planar edge or surface and a non-planar edge or surface defined by trench 301, which may be a squared off U shape, a rounded U shape, a V shape, or the like. As shown, conformal capacitor surface 707 includes only first electrode layer 701 while planar capacitor surface 706 includes a region of each of first electrode layer 701, dielectric layer 702, and second electrode layer 703, with dielectric layer 702being a dielectric material between the metal materials of first electrode layer 701 and second electrode layer 703.

Returning to FIG. 1, processing continues at operation 104, where the substrate workpiece and the capacitor components formed therein are cut or otherwise segmented to form sub-modules, patches, or sub-patches that have both a desired length for deployment in a package substrate cavity or opening (as discussed herein below) and include capacitor components having a desired capacitor length based on the desired capacitance, materials deployed, width and depth dimensions, and so on of the current capacitor applications. Notably the cut or segmented also exposes eventual electrode contact regions at edges of the substrate and capacitor components that will be used to contact the vertically embedded capacitor components.

FIG. 8 illustrates a capacitor structure 800 similar to capacitor structure 700 during a segmentation operation 801 to divide substrate 201 and capacitor components 705 such that a segmented portion of substrate 201 and capacitor components 705 may be optionally stacked and deployed vertically within a package substrate. Segmentation operation 801 may be performed using any suitable technique or techniques such as cutting techniques. In some embodiments, segmentation operation 801 forms a cut orthogonal to capacitor components 705. Although illustrated with linear capacitor components 705, other shapes may be used as discussed with respect to FIGS. 3C, 3D, 3E, 3F, and elsewhere herein.

FIG. 9 illustrates a capacitor structure 800 similar to capacitor structure 800 after segmentation operation 801 divides substrate 201 and capacitor components 705 to form substrates 901 and trench capacitor structures 903. In the illustrated example, substrate 201 and capacitor components 705 are divided into identical substrates 901 and trench capacitor structures 903. However, the formed substrates and trench capacitor structures 903 may be different. Furthermore, multiple segmentation operations 801 may be performed along capacitor components 705 to divide capacitor components 705 into any number of capacitor structures including capacitor structures having contact access from two sides of the capacitor structures. In the example of FIG. 9, capacitor structures 903 are linear capacitor structures. However, any suitable shapes may be formed including cross shape, a T-shape, a partial oval shape, a diagonal line, or the like.

As shown, substrate 201 is divided into substrate 901 having a length Ls. Ls may be any suitable structure length and the length may be defined ultimately as a depth as substrate 901 will be vertically integrated into a package assembly. Notably, an advantage of the techniques discussed herein is the ability to deploy capacitor structures 903 having any suitable shape (e.g., in the x-y plane) and nearly any length in the y-dimension. For example, the length and size of capacitor structures 903 in the x-y plane is only limited by the size of substrate 201. In some embodiments, length Ls is in the range of 0.2 mm to about 500 mm. In some embodiments, length Ls is not less than 1 mm. In some embodiments, length Ls matches or is within 10% of a substrate core thickness into which substrate 901 will be inserted. In some embodiments, length Ls is in the range of 1 to 7 mm, but longer lengths can be used as discussed above. In some embodiments, length Ls is not less than 2 mm, not less than 4 mm, or not less than 5 mm, not less than 10 mm, or more. Similarly, segmentation operation 801 and the patterning of openings 301 defines a length Lc of trench capacitor structures 903. Length Lc of trench capacitor structures 903 may be any suitable length to provide the electrical characteristic desired from trench capacitor structures 903. Again, the length Lc of capacitor structures 903 is only limited by the size of substrate 201. In some embodiments, length Lc is not less than 0.75 mm. In some embodiments, length Lc is in the range of 1 to 7 mm, but longer lengths can be used. In some embodiments, length Lc is in the range of 2 mm to 4 mm. In some embodiments, length Lc is not less than 1 mm, not less than 2 mm, not less than 4 mm, not less than 5 mm, not less than 10 mm, or more. Other lengths may be used.

Also as shown, segmentation operation 801 reveals an edge 911 of substrates 901 that includes (as shown in cross-sectional side view 220) locations or regions for contacting trench capacitor structures 903 by metallization, metal contacts, or the like. For example, region 912 may be contacted by a metallization structure to provide electrical routing to first electrode layer 701 and region 913 may be contacted by a metallization structure to provide electrical routing to second electrode layer 703. Such regions 912, 913 may be formed on each of trench capacitor structures 903 and regions 912, 913 may define metallization patterns, contact patterns or the like to couple to trench capacitor structures 903. Regions 912, 913 may have any suitable pattern, shape, contact area, and so on.

As discussed, trench capacitor structures 903 are embedded within openings 301 (refer to FIG. 3) and both trench capacitor structures 903 and openings 301 extend along a length of surface 302 of substrate 201. As used herein the terminology along a length of a surface of a substrate indicates the component is aligned with (e.g., the longest or major component) is aligned with the planar working surface of the substrate and is substantially orthogonal to the planar working surface. For example, the length (e.g., the longest or major component) extends along surface 302 of substrate 201 with surface 302 being in the x-y plane and orthogonal to the depth or thickness of the substrate 201, which is in the z-dimension. With reference to FIG. 3, trench capacitor structures 903 and openings 301 extend along length Lt, which is in the x-y plane and orthogonal to the z-dimension.

FIG. 9 further provides a cross-sectional side view 930 of capacitor structure 900 to illustrate the embedded nature of trench capacitor structures 903. For example, cross-sectional side view 930 is taken at the B-B′ plane shown in top-down view 210. In cross-sectional side view 930, an outline of trench capacitor structures 903 illustrates that trench capacitor structures 903 extend in the y-dimension partially across length Ls of substrate 901 such that a portion 904 of the bulk material of substrate 201, 901 is between each of trench capacitor structures 903 and an edge 914 of substrate 901 such that edge 914 is opposite edge 911 (i.e., the edge including contact regions 912, 913 and corresponding exposed portions of first electrode layer 701 and second electrode layer 703).

FIG. 10 illustrates a capacitor structure 1000 similar to capacitor structure 900, which illustrates an alternative embodiment where first electrode layer 701, dielectric layer 702, and second electrode layer 703 extend entirely through substrate 201. As shown, trenches 301 may, in some embodiments, extend entirely through substrate 201 such that first electrode layer 701, dielectric layer 702, and second electrode layer 703 also extend through surface 303. Such embodiments may offer increased capacitor area for trench capacitor structures 903. The planarization processing discussed with respect to FIG. 7 may be performed on both surfaces 302, 303 to provides planar capacitor surfaces 706, 1007 of capacitor components 705 that are substantially coplanar with surface 302, 303 of substrate 201 (i.e., in the x-y plane).

Returning to FIG. 1, processing continues at operation 105, where the capacitor sub-modules formed at operation 104 may be stacked or mounted on top of one another and glued together by adhesion layers between the sub-modules. Any number of sub-modules may be stacked together to form a capacitor module having multiple capacitor sub-modules such as 2, 3, 4, 5, or more sub-modules. In some embodiments, such sub-module stacking is bypassed, and a single sub-module may be deployed. The sub-modules may be stacked using any suitable technique or techniques such as pick-and-place operations and the sub-modules may be glued to one another by any suitable adhesive, tape, or the like. In some embodiments, the adhesive is a polymer material such as epoxy. As used herein, the term polymer material indicates a material of large molecules with substantially repeating sub-units, and epoxies are thermosetting polymer materials. Processing continues at operation 106, where the assembled capacitor modules are output and prepared for further assembly by rotating the assembled capacitor modules and applying an optional adhesion layer or film on a non-functional surface of the capacitor module.

FIG. 11 illustrates a capacitor module 1100 assembled by stacking multiple capacitor structures such as capacitor structures 900. FIG. 11 provides a rotated side view 1110 and a side view 1120, with side view 1120 is taken at the C-C′ shown in rotated side view 1110. Although illustrate with respect to capacitor structures 900 of the same size, capacitor structure 1000 may be deployed in capacitor module 1100 and capacitor module 1100 may include capacitor structures with any different characteristics. As shown in FIG. 11, capacitor module 1100 includes a number of capacitor structures 900 each having trench capacitor structures 903 embedded in substrates 901.

Each of substrates 901 is bonded to a neighboring one of substrates 901 by an adhesion layer 1101 which couples adjacent substrates 901. Adhesion layer 1101 also provides insulation for trench capacitor structures 903 and adhesion layer 1101 may be characterized as an insulator layer, a bonding layer, an adhesive, or the like. Adhesion layer 1101 may be any suitable material such as a polymer material. In some embodiments, adhesion layer 1101 is an epoxy.

As shown, in some embodiments, capacitor module 1100 includes capacitor structures 900, each including trench capacitor structures 903 embedded within corresponding openings 301 that extend along a length of surface 302 of substrate 901 (refer to FIG. 3). Capacitor module 1100 further includes an insulator layer or adhesion layer 1101 on surface 302 of one of substrates 901 and on an opposite surface 303 of an adjacent one of substrates 901. Trench capacitor structures 903 are exposed at combined edge 911, which is a coplanar combination of each edge 911 of trench capacitor structures 903. For example, each edge 911 extends between surfaces 302, 303 as discussed herein.

In some embodiments, each surface 302 of substrate 901 (e.g., surfaces having trench capacitor structures 903) are in the same direction (e.g., the z-dimension) such that surface 302 is on one side of adhesion layer 1101 and surface 303 of a neighboring substrate 901 is on the other side of adhesion layer, as shown. In other embodiments, the directions of substrates may be varied such that both surfaces 302 (e.g., surfaces having trench capacitor structures 903) are on opposite sides of the same adhesion layer 1101 or such that surfaces 303 (e.g., surfaces opposite trench capacitor structures 903) are on opposite sides of the same adhesion layer 1101.

FIG. 12 illustrates a capacitor module 1200 similar to capacitor module 1100 after rotation and preparation for being embedded in an organic package assembly substrate, and after application of an optional adhesive film 1201. As shown, capacitor module 1200 may be rotated 90 degrees into a vertical integration in preparation for further assembly by mounting the vertically oriented capacitor module 1200 in a substrate core cavity. Such rotation and alignment may be performed using any suitable technique or techniques such as pick-and-place operations. In addition, adhesive film 1201 may be applied using any suitable technique or techniques. Adhesive film 1201 may be any adhesive layer such as a tape or a glue. Adhesive film 1201 may aid in assembly during the placement of capacitor module 1200 into a cavity in a package substrate.

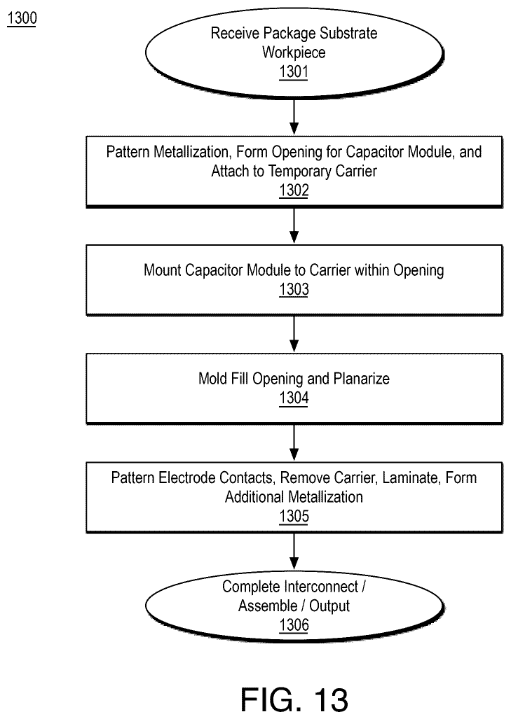

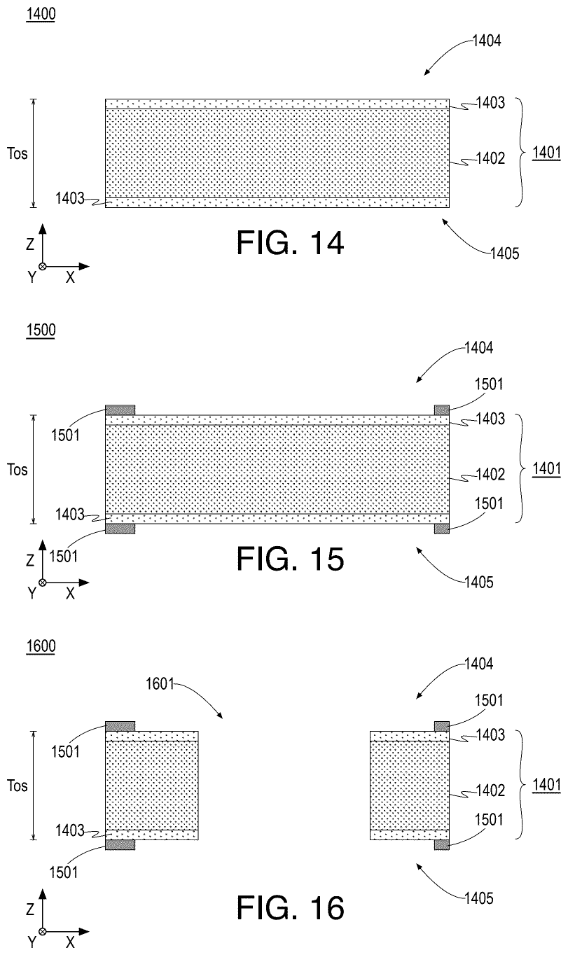

FIG. 13 is a flow diagram illustrating methods 1300 for assembling a package including a vertical capacitor module including a number of stacked substrates each including a number of capacitor structures embedded in a package substrate, arranged in accordance with some embodiments of the disclosure. Methods 1300 may be practiced, for example, to fabricate any package, package structure, assembly, apparatus, or system discussed herein. FIGS. 14, 15, 16, 17, 18, 19, 20, 21, 21, 22, 23, 24, 25, 26, and 27 illustrate cross-sectional side views of package structures evolving as methods 1300 are practiced, arranged in accordance with some embodiments of the disclosure. For example, methods 1300 illustrate a process flow for assembling 2D pre-formed capacitor patches or modules package architectures.

Methods 1300 begin at input operation 1301, where a workpiece including a package substrate or similar substrate into which a capacitor module is to be embedded is received. The workpiece includes any suitable substrate material or material layers. In some embodiments, the received workpiece is a package substrate such as an organic substrate including an organic core. In some embodiments, the substrate is or includes a thick organic core. However, other substrate materials may be used.

FIG. 14 illustrates a cross-sectional side view of a package structure 1400 illustrating a received substrate 1401. Substrate 1401 may be characterized as an organic substrate, an electronic substrate, a board, or the like. Substrate 1401 may be any appropriate structure, including, but not limited to, an interposer, a board, or the like. Substrate 1401 may have a first or top surface 1404 and an opposing second or bottom surface 1405. Substrate 1401 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like. In some embodiments, substrate 1401 includes a core 1402 and build-up layers 1403. However, substrate may have any suitable characteristics that provides a substrate thickness Tos that allows for embedding and mounting devices, circuitry, and the like. For example, core 1402 may be a substrate of an integrated circuit package built upon a board, card, or wafer comprising a non-flexible stiff material. A relatively small, printed circuit board may be used as core 1402, and integrated circuit device and other components may be soldered to a surface of the board. In some embodiments, core 1402 has vias extending from one side to the other, allowing circuitry on one side of the core to be coupled directly to circuitry on the opposite side of core 1402. In some embodiments, core 1402 also serves as a platform for building up layers of conductors and dielectric materials.

Returning to FIG. 13, processing continues at operation 1302, where metallization may be patterned on the received substrate, an opening or cavity may be formed to house a capacitor module, and the substrate may be attached to a temporary carrier or support substrate. The metallization may be patterned using any suitable technique or techniques such as subtractive or additive metallization patterning techniques. In some embodiments, the metallization includes patterned copper for routing to the capacitor module and/or external devices. In some embodiments, the metallization includes patterned through holes to provide electrical coupling for the frontside and backside of the substrate. The opening or cavity may be formed using any suitable technique or techniques such as mechanical drilling techniques. The opening or cavity may be formed at any suitable dimensions to house one or more of the capacitor modules discussed and, optionally, other components. The substrate may be attached to the temporary carrier or support substrate using any suitable technique or techniques such as by application of a releasable adhesive. The carrier or support substrate may be any suitable material.

FIG. 15 illustrates a package structure 1500 similar to package structure 1400 after formation of metallization 1501. Metallization 1501 may be formed using subtractive or additive metallization patterning techniques and metallization 1501 may include any suitable conductive metals such as copper. In some embodiments, metallization 1501 includes patterned through holes (not shown) that provide electrical coupling between top surface 1404 and bottom surface 1405 of substrate 1401.

FIG. 16 illustrates a package structure 1600 similar to package structure 1500 after formation of opening 1601. As shown, in some embodiments, opening 1601 extends through the entirety of thickness Tos of substrate 1401. In some embodiments, opening 1601 extends only through a portion of thickness Tos of substrate 1401 such that a portion of substrate 1401 extending to bottom surface 1405 remains. Although illustrated with respect to opening 1601 extending through the entirety of thickness Tos of substrate 1401, the following structures pertain to examples where a portion of thickness Tos of substrate 1401 remains.

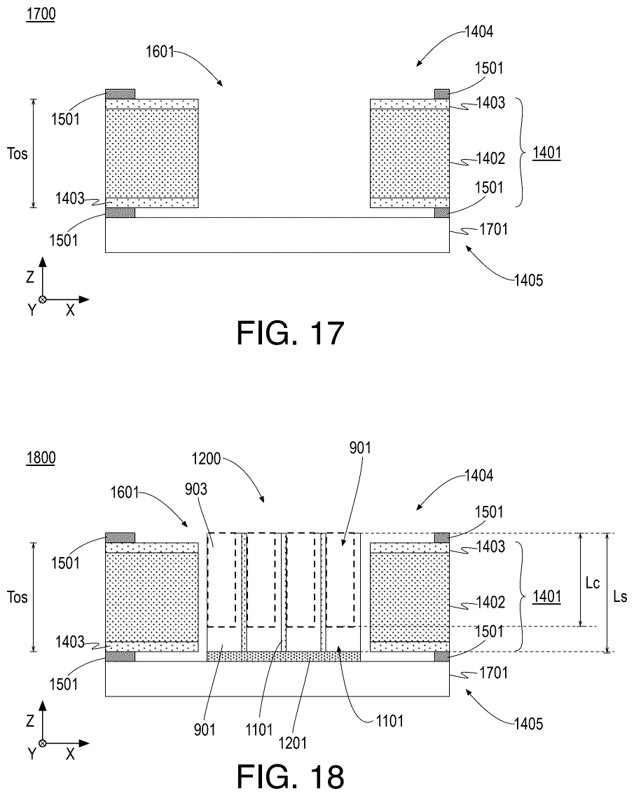

FIG. 17 illustrates a package structure 1700 similar to package structure 1600 after the attachment of temporary carrier 1701. Package structure 1600 may be attached to temporary carrier 1701 using any suitable technique or techniques such as a releasable adhesive layer. Temporary carrier 1701 may provide a surface for the mounting of a capacitor module as well as rigidity during mounting.

Returning to FIG. 13, processing continues at operation 1303, where a capacitor module fabricated as discussed with respect to methods 100 is mounted or attached within the opening formed at operation 1302. The capacitor module may have any number of substrates bonded together. Similarly, each capacitor module may have any number of capacitors having any suitable characteristics. In some embodiments, the capacitor module is a single substrate. In some embodiments, the capacitor module has multiple substrates stacked and bonded using an adhesive layer such as 2, 3, 4, 5, or more substrates and corresponding capacitor structures.

FIG. 18 illustrates a package structure 1800 similar to package structure 1700 after mounting capacitor module 1200 within opening 1601. Although illustrated with respect to capacitor module 1200, any capacitor module discussed herein may be mounted within opening 1601. As shown, in some embodiments, adhesive film 1201 is used to bond capacitor module 1200 to temporary carrier 1701. Furthermore, the length Ls of substrates 901 spans an entirety of the thickness Tos of substrate 1401. For example, FIG. 18 illustrates an example glass substrate deep trench capacitor vertically aligned mounting within opening 1601 of substrate 1401. In some embodiments, the length Ls of substrates 901 is substantially the same as the thickness Tos of substrate 1401. In some embodiments, the length Ls of substrates 901 is substantially the same as the thickness Tos of substrate 1401 plus the thickness of metallization 1501.

As shown in FIG. 18, thickness Tos (i.e., extending in the z-dimension) of substrate 1401 is orthogonal to top surface 1404 of substrate 1401 (i.e., top surface 1404 is in the x-y plane) such that surfaces 302 (i.e., in the y-z plane) and surfaces 303 (i.e., in the y-z plane) of each of substrates 901 is also orthogonal to top surface 1404 of substrate 1401. That is, substrates 901 have an orthogonal orientation with respect to substrate 1401 such that substrates 901 and capacitor module 1200 are vertically oriented with respect to the working top surface 1404 of substrate 1401 (which is horizontally or laterally oriented).

Such thickness matching (and vertical orientation) reduces process difficulty with respect to x-, y-, z-alignment, rotational shift, tilting, and the like with respect to mounting capacitor module 1200 within opening 1601 in substrate 1401. Furthermore, the thickness matching and discussed processing allows for the same fiducials to be used in the mechanical drilling process used to form opening 1601 and the pick-and-place operation used to mount capacitor module 1200, which offers improved alignment. For example, the placement of capacitor module 1200 may be characterized as direct alignment due to the pick-and-place operation using the same fiducials as the mechanical drilling process used to form opening 1601.

Returning to FIG. 13, processing continues at operation 1304, where the volume of the opening not occupied by the mounted capacitor module(s) and any other components is filled with a mold material and the mold material is subsequently planarized. The mold material may be any suitable insulator material such as a polymer, an epoxy, a build-up material, an organic fill material, or the like. The mold material may be characterized as an encapsulation dielectric, an encapsulation dielectric layer, an encapsulation dielectric material, or the like. In some embodiments, the mold material is the same material used in adhesion layer 1101 to adhere substrates 901 to one another. However, adhesion layer 1101 and the mold material may be different. The mold material may be formed within the remaining portion of the opening using any suitable technique or techniques. In some embodiments, the old material is laminated, coated, or filled by an encapsulation process. For example, the encapsulation process may be one of vacuum lamination, liquid coating, a mold process, or the like. Subsequently, the mold material is planarized using any suitable technique or techniques such as grinding or polishing operations to remove the overburden of the mold material.

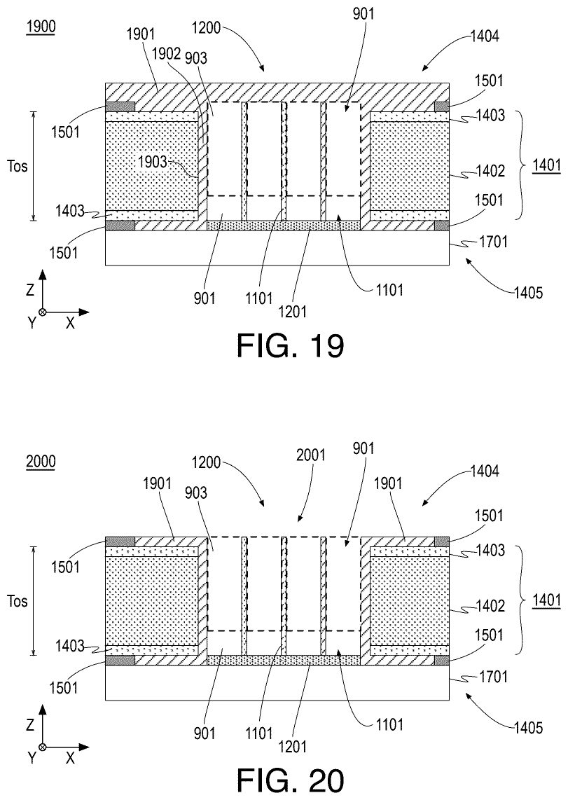

FIG. 19 illustrates a package structure 1900 similar to package structure 1800 after the formation of a mold material 1901 within the remaining portions of opening 1601. Mold material 1901 may be a polymer, an epoxy, a build-up material, an organic fill material, or the like and mold material 1901 fills or substantially fills the remaining portions of opening 1601. In some embodiments, mold material 1901 and adhesion layer 1101 are the same material, although they may be different. As shown, in some embodiments, planar capacitor surface 706 (refer to FIG. 7) of trench capacitor structures 903 of the left-most substrate 901 may be in direct contact with a portion 1902 mold material 1901, such that mold material 1901 provides insulation of the corresponding trench capacitor structures 903. As shown, portion 1902 extends from surface 302 (i.e., the surface having trench capacitor structures 903) of the left-most substrate 901 to a sidewall 1903 of substrate 1401.

FIG. 20 illustrates a package structure 2000 similar to package structure 1900 after the planarization of mold material 1901 to remove the overburden material and to expose surface 2001 which exposes regions such as regions 912, 913 at edge 911 (refer to FIG. 9) for making electrical contact to trench capacitor structures 903.

Returning to FIG. 13, processing continues at operation 1305, where contact electrode contacts are patterned to couple to the vertically aligned capacitor structures, the temporary carrier is removed, and additional dielectric (e.g., laminate) and metallization may be formed. The electrode contacts may be formed using any suitable technique or techniques such as subtractive or additive metallization patterning techniques. The temporary carrier may be removed using any suitable technique or techniques such as UV based release, chemical treatment, heat treatment, or others. The additional dielectric (e.g., laminate) and metallization may be formed using any suitable technique or techniques known in the art.

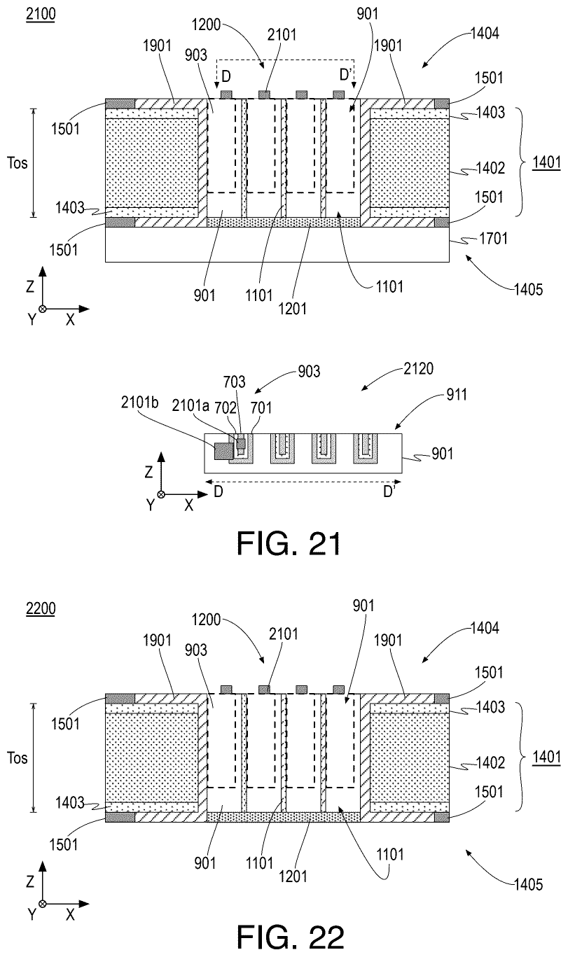

FIG. 21 illustrates a package structure 2100 similar to package structure 2000 after formation of electrode contacts 2101. Electrode contacts 2101 may be formed using any suitable technique or techniques such as subtractive or additive metallization patterning techniques and electrode contacts 2101 may include any suitable conductive material such as copper. For example, electrode contacts 2101 may be characterized as copper pads, bond pads, electrode pads, or the like. FIG. 21 further provides a top-down view 2120 of package structure 2100 to illustrate electrode contact 2101a making contact to second electrode layer 703 and electrode contact 2101b making contact to first electrode layer 701 at edge 911. In some embodiments, one or both of electrode contact 2101a, 2101b includes a trace portion extending from second electrode layer 703 or first electrode layer 701. For example, electrode contacts 2101 provide contact to trench capacitor structures 903 and may further provide routing to and from trench capacitor structures 903. In some embodiments, electrode contacts 2101 provide contact and such routing or redistribution routing is provided by higher level metallization features.

FIG. 22 illustrates a package structure 2200 similar to package structure 2100 after removal of temporary carrier 1701. Temporary carrier 1701 may be removed using any suitable technique or techniques such as UV based release, chemical treatment, heat treatment, or others. As shown, removal of temporary carrier 1701 reveals bottom surface 1405 of capacitor module 1200. Notably, when capacitor module 1200 includes contacts on both edges of capacitor module 1200 (for example if two cuts are made at segmentation operation 801), electrode contacts in analogy to electrode contacts 2101 may be made to trench capacitor structures 903 at bottom surface 1405.

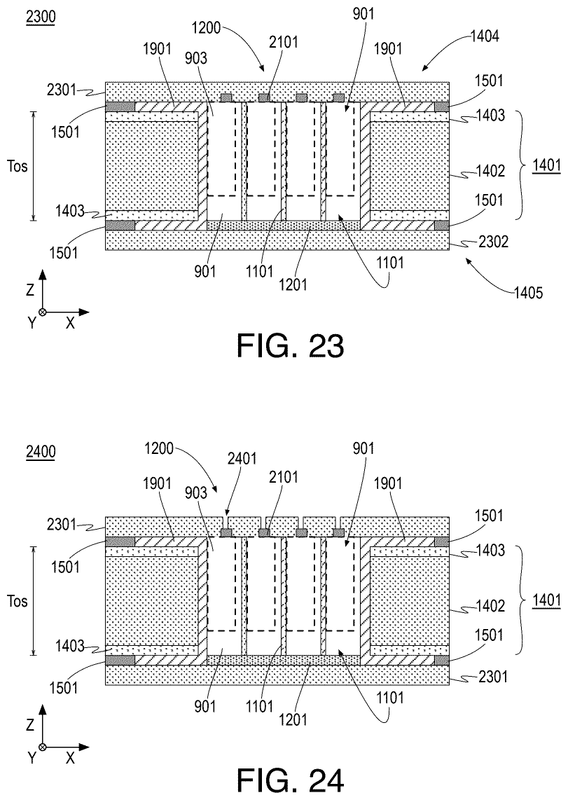

FIG. 23 illustrates a package structure 2300 similar to package structure 2200 after formation of dielectric layers 2301, 2302. Dielectric layers 2301, 2302 may be formed using any suitable technique or techniques such as lamination techniques. In some embodiments, dielectric layers 2301, 2302 are build-up layers or films. As shown, In some embodiments, dielectric layer 2301 is over top surface 1404 and dielectric layer 2301 is over bottom surface 1405. In some embodiments, only dielectric layer 2301 is formed over top surface 1404.

FIG. 24 illustrates a package structure 2400 similar to package structure 2300 after formation of openings 2401 in dielectric layers 2301, 2302. Openings 2401 may be formed using any suitable technique or techniques such as laser drilling techniques to expose underlying electrode contacts 2101. In embodiments, where trench capacitor structures 903 are accessible from bottom surface 1405, openings may be formed in dielectric layer 2302.

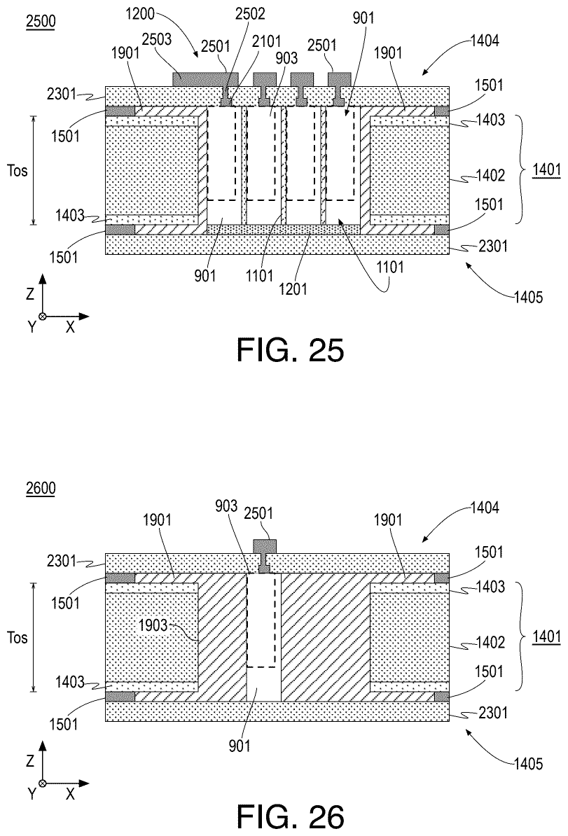

FIG. 25 illustrates a package structure 2500 similar to package structure 2400 after formation of metallization features 2501 that couple to electrode contacts 2101. Metallization features 2501 may be formed using any suitable technique or techniques such as additive or subtractive metallization processes. In some embodiments, metallization features 2501 include a via portion 2502 that extends through opening 2401 and a line portion 2503 that extends from via portion 2502 and is on dielectric layer 2301. As shown, in some embodiments, via portion 2502 is coupled to electrode contacts 2101 and line portion 2503 of metallization feature 2501 extends over substrate 1401.

FIG. 26 illustrates a package structure 2600 similar to package structure 2500, which illustrates an alternative embodiment where a single substrate 901 and corresponding trench capacitor structures 903 are deployed. In such embodiments, planar capacitor surface 706 (refer to FIG. 7) of trench capacitor structures 903 may be in direct contact with mold material 1901, such that mold material 1901 provides insulation of the corresponding trench capacitor structures 903, and mold material extends to sidewall 1903 of substrate 1401. For example,

Returning to FIG. 13, processing continues at operation 1306, where any remaining interconnect features, including dielectric deposition, metallization routing, and the like may be competed, the package substrate may be assembled by affixing integrated circuit dies and other processing, and the resultant structure maybe output. In some embodiments, the terminals or metallization features coupled to the capacitor structure are bonded to integrated circuit dies or other circuitry and the package substrate is assembled into an assembly including the integrated circuit dies, the package substrate, optional interconnect bridges, an optional board such as a motherboard, and optional thermal solutions, as is known in the art. The assembly or package substrate may then be installed in any suitable electronic device such as a laptop, a netbook, a notebook, an ultrabook, a smartphone, a tablet, a personal digital assistant PDA, an ultra-mobile PC, a mobile phone, a desktop computer, a server, a printer, a scanner, a monitor, a set-top box, an entertainment control unit, a digital camera, a portable music player, a digital video recorder, or the like.

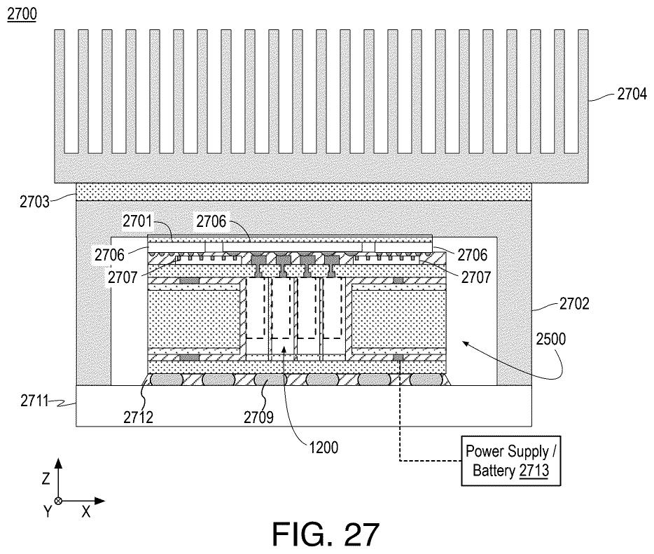

FIG. 27 illustrates an example microelectronic device assembly 2700 including a vertically embedded 2D pre-formed capacitor module, in accordance with some embodiments. Although illustrated with capacitor module 1200 and package structure 2500, any capacitor module or single substrate capacitor structure discussed herein may be embedded in any suitable package structure for deployment in microelectronic device assembly 2700. As shown in FIG. 27, microelectronic device assembly 2700 may include any number of integrated circuit dies 2706 and/or bridge dies 2707 mounted to package structure 2500 via die level interconnects, redistribution layers, metallization routings, and the like. For example, integrated circuit dies 2706 may be coupled to trench capacitor structures 903. In some embodiments, such interconnect or conductive features are embedded in a mold material such as mold material 1901. Although illustrated with respect to three integrated circuit dies 2706 (e.g., a compute die, a memory die, and a transceiver) and two bridge dies 2707 (e.g., embedded multi-die interconnect bridges), any number of integrated circuit dies, 3D stacked multichip device, multi-chip composite structure, or the like may be deployed in microelectronic device assembly 2700. In some embodiments, package structure 2500is coupled to a board 2711 via package level interconnects 2709 and partially encapsulated by underfill material 2712.

Microelectronic device assembly 2700 further includes a power supply 2713 coupled to one or more of board 2711, package structure 2500, integrated circuit dies 2706, or other components of microelectronic device assembly 2700. Power supply 2713 may include a battery, voltage converter, power supply circuitry, or the like. Microelectronic device assembly 2700 further includes a thermal interface material (TIM) 2701 disposed on top surfaces of integrated circuit dies 2706. TIM 2701 may include any suitable thermal interface material and may be characterized as TIM 1. Integrated heat spreader 2702 having a surface on TIM 2701 extends over integrated circuit dies 2706 and package structure 2500, and is mounted to board 2711. Board 2711 may include any suitable substrate such as a motherboard, interposer, or the like. Microelectronic device assembly 2700 further includes TIM 2703 disposed on a top surface of integrated heat spreader 2702. TIM 2703 may include any suitable thermal interface material and may be characterized as TIM 2. TIM 2701 and TIM 2703 may be the same materials, or they may be different. Heat sink 2704 (e.g., an exemplary heat dissipation device or thermal solution) is on TIM 2703 and dissipates heat. Microelectronic device assembly 2700 may be used in desktop and server form factors. In other contexts, a heat solution such as a heat pipe or heat spreader may be mounted directly on TIM 2701. Such assemblies may be used in smaller form factor devices. Other heat dissipation devices may be used.

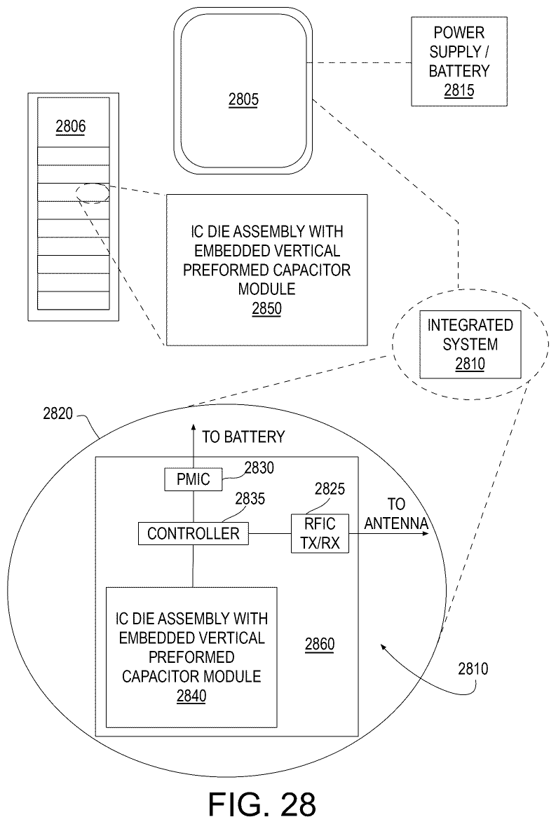

FIG. 28 illustrates exemplary systems deploying a vertically embedded 2D pre-formed capacitor module, in accordance with some embodiments. The system may be a mobile computing platform 2805 and/or a data server machine 2806, for example. Either may employ a component assembly including a vertically embedded 2D pre-formed capacitor module as described herein. Server machine 2806 may be any commercial server, for example, including any number of high-performance computing platforms disposed within a rack and networked together for electronic data processing, which in the exemplary embodiment includes an integrated circuit (IC) die assembly 2850 with a vertically embedded 2D pre-formed capacitor module as described elsewhere herein. Mobile computing platform 2805 may be any portable device configured for each of electronic data display, electronic data processing, wireless electronic data transmission, or the like. For example, mobile computing platform 2805 may be any of a tablet, a smart phone, a laptop computer, etc., and may include a display screen (e.g., a capacitive, inductive, resistive, or optical touchscreen), a chip-level or package-level integrated system 2810, and a battery 2815. Although illustrated with respect to mobile computing platform 2805, in other examples, chip-level or package-level integrated system 2810 and battery 2815 may be implemented in a desktop computing platform, an automotive computing platform, an internet of things platform, or the like. As discussed below, in some examples, the disclosed systems may include a sub-system 2860 such as a system on a chip (SOC) or an integrated system of multiple ICs, which is illustrated with respect to mobile computing platform 2805.

Whether disposed within integrated system 2810 illustrated in expanded view 2820 or as a stand-alone packaged device within data server machine 2806, sub-system 2860 may include memory circuitry and/or processor circuitry 2840 (e.g., RAM, a microprocessor, a multi-core microprocessor, graphics processor, etc.), a power management integrated circuit (PMIC) 2830, a controller 2835, and a radio frequency integrated circuit (RFIC) 2825 (e.g., including a wideband RF transmitter and/or receiver (TX/RX)). As shown, one or more IC dies, such as memory circuitry and/or processor circuitry 2840 may be packaged, assembled and implemented, such that the package has one or more vertically embedded 2D pre-formed capacitor modules as described herein. In some embodiments, RFIC 2825 includes a digital baseband and an analog front end module further comprising a power amplifier on a transmit path and a low noise amplifier on a receive path). Functionally, PMIC 2830 may perform battery power regulation, DC-to-DC conversion, etc., and so has an input coupled to battery 2815, and an output providing a current supply to other functional modules. As further illustrated in FIG. 28, in the exemplary embodiment, RFIC 2825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 2840 may provide memory functionality for sub-system 2860, high level control, data processing and the like for sub-system 2860. In alternative implementations, each of the SOC modules may be integrated onto separate ICs coupled to a package substrate, interposer, or board.

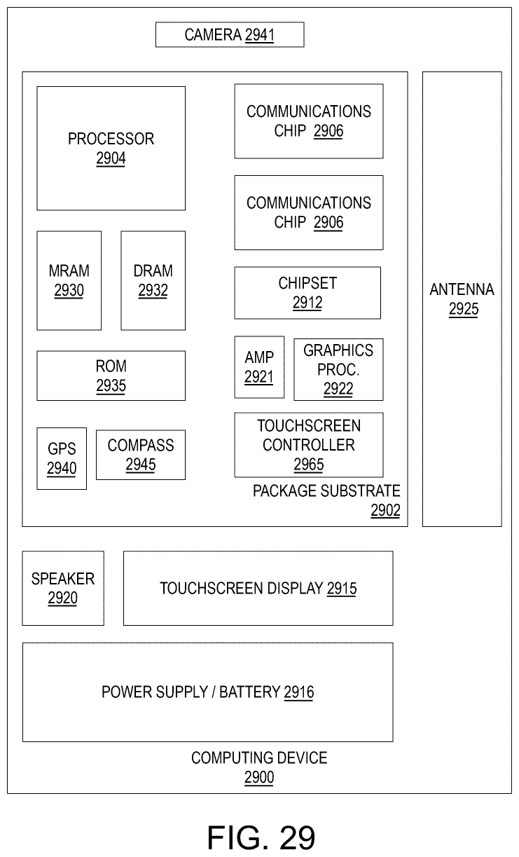

FIG. 29 is a functional block diagram of an electronic computing device 2900, in accordance with some embodiments. For example, device 2900 may, via any suitable component therein, employ a vertically embedded 2D pre-formed capacitor module in accordance with any embodiments described elsewhere herein. Device 2900 further includes a motherboard or package substrate 2902 hosting a number of components, such as, but not limited to, a processor 2904 (e.g., an applications processor). Processor 2904 may be physically and/or electrically coupled to package substrate 2902. In some examples, processor 2904 is within a packaged IC assembly that includes a vertically embedded 2D pre-formed capacitor module as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 2906 may also be physically and/or electrically coupled to the package substrate 2902. In further implementations, communication chips 2906 may be part of processor 2904. Depending on its applications, computing device 2900 may include other components that may or may not be physically and electrically coupled to package substrate 2902. These other components include, but are not limited to, volatile memory (e.g., DRAM 2932), non-volatile memory (e.g., ROM 2935), flash memory (e.g., NAND or NOR), magnetic memory (MRAM 2930), a graphics processor 2922, a digital signal processor, a crypto processor, a chipset 2912, an antenna 2925, touchscreen display 2915, touchscreen controller 2965, battery 2916, audio codec, video codec, power amplifier 2921, global positioning system (GPS) device 2940, compass 2945, an accelerometer, a gyroscope, speaker 2920, camera 2941, and mass storage device (such as hard disk drive, solid-state drive (SSD), compact disk (CD), digital versatile disk (DVD), and so forth, or the like.

Communication chips 2906 may enable wireless communications for the transfer of data to and from the computing device 2900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 2906 may implement any of a number of wireless standards or protocols, including, but not limited to, those described elsewhere herein. As discussed, computing device 2900 may include a plurality of communication chips 2906. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises one or more first capacitor structures embedded within corresponding first openings that extend along a length of a first surface of a first substrate, the first surface opposite a second surface of the first substrate, wherein each of the first capacitor structures comprises a capacitor surface substantially coplanar with the first surface of the first substrate, an insulator layer on the first surface of the first substrate and on each capacitor surface, wherein first electrodes and second electrodes of the first capacitor structures are exposed at an edge of the first substrate extending between the first surface and the second surface of the first substrate, and one or more second capacitor structures embedded within corresponding second openings that extend along a length of a first surface of a second substrate, the first surface opposite a second surface of the second substrate, wherein the first or second surface of the second substrate is on the insulator layer.

In one or more second embodiments, further to the first embodiments, each of the capacitor surfaces comprises a region of each of the first electrode, the second electrode, and a dielectric material between the first electrode and the second electrode.

In one or more third embodiments, further to the first or second embodiments, the second surface of the second substrate is on the insulator layer, and the apparatus further comprises a second insulator layer on the first surface of the second substrate and on the second capacitor structures and one or more third capacitor structures embedded within corresponding third openings that extend along a length of a first surface of a third substrate, the first surface opposite a second surface of the second substrate, wherein the second surface of the third substrate is on the second insulator layer.

In one or more fourth embodiments, further to the first through third embodiments, the edge of the first substrate is a first edge, and wherein a portion of the first substrate is between each of the first capacitor structures and a second edge of the first substrate opposite the first edge of the first substrate.

In one or more fifth embodiments, further to the first through fourth embodiments, the insulator layer comprises a polymer material.

In one or more sixth embodiments, further to the first through fifth embodiments, the first substrate and the second substrate each comprise a layer of glass that is rectangular in shape along the first surface of the first substrate and the first surface of the second substrate.

In one or more seventh embodiments, further to the first through sixth embodiments, the first capacitor structures, first substrate, insulator layer, second capacitor structures, and second substrate comprise a capacitor module, the capacitor module extending at least partially through a thickness of an organic substrate orthogonal to a top surface of the organic substrate, wherein the first surface of the first substrate is substantially orthogonal to the top surface of the organic substrate.

In one or more eighth embodiments, further to the first through seventh embodiments, the thickness of the organic substrate is not less than 1 mm, and wherein a length of the first capacitor structures extending along the thickness is not less than 0.75 mm.

In one or more ninth embodiments, further to the first through eighth embodiments, the apparatus further comprises a first contact coupled to one of the first electrodes at the edge, a second contact coupled to one of the second electrodes at the edge, a metallization coupled to the first contact and extending over the organic substrate, and an integrated circuit die coupled to the metallization.

In one or more tenth embodiments, a system comprises an IC die and/or a power supply coupled to the one or more first capacitor structures of the first through eight embodiments.

In one or more eleventh embodiments, an apparatus comprises one or more capacitor structures embedded within corresponding openings in a first surface of an inorganic substrate, the first surface opposite a second surface of the inorganic substrate, an organic substrate, wherein the inorganic substrate extends at least partially through a thickness of the organic substrate orthogonal to a top surface of the organic substrate, such that the first surface of the inorganic substrate is orthogonal to the top surface of the organic substrate, a polymer material on the first surface of the inorganic substrate and the capacitor structures, and first and second contacts coupled to first and second electrodes of one of the capacitor structures at an edge of the inorganic substrate extending from the first surface of the inorganic substrate to the second surface of the inorganic substrate.

In one or more twelfth embodiments, further to the eleventh embodiments, the polymer material is on a second surface of the inorganic substrate opposite the first surface of the inorganic substrate and on a sidewall of the organic substrate.

In one or more thirteenth embodiments, further to the eleventh or twelfth embodiments, the apparatus further comprises one or more second capacitor structures embedded within corresponding openings in a first surface of a second inorganic substrate, wherein the polymer material is on the first surface of the second inorganic substrate or on a second surface of the second inorganic substrate opposite the first surface of the second inorganic substrate.

In one or more fourteenth embodiments, further to the eleventh through thirteenth embodiments, the polymer material is an adhesive epoxy, and the apparatus further comprises a mold material on a second surface of the inorganic substrate opposite the first surface of the inorganic substrate and on a sidewall of the organic substrate.

In one or more fifteenth embodiments, further to the eleventh through fourteenth embodiments, the thickness of the organic substrate is not less than 1 mm, and wherein a length of the capacitor structures extending along the thickness is not less than 0.75 mm.

In one or more sixteenth embodiments, further to the eleventh through fifteenth embodiments, the openings in the first surface of the inorganic substrate have a cross-sectional shape orthogonal to the first surface, the cross-sectional shape comprising one of a cross shape, a T-shape, a partial oval shape, or a diagonal line.

In one or more seventeenth embodiments, further to the eleventh through sixteenth embodiments, the apparatus further comprises an integrated circuit die coupled to one of the capacitor structures.

In one or more eighteenth embodiments, a system comprises an IC die and/or a power supply coupled to the one or more first capacitor structures of the eleventh through seventeenth embodiments.

In one or more nineteenth embodiments, a method comprises forming one or more trench capacitor structures embedded within corresponding openings that extend along a length of a surface of a substrate, segmenting the substrate and the one or more trench capacitor structures to form a first capacitor sub-module comprising a portion of the substrate and portions of the trench capacitor structures, and stacking a plurality of capacitor sub-modules including the first capacitor sub-module via one or more adhesive layers between surfaces of substrates of the capacitor sub-modules to form a capacitor module, wherein electrodes of the trench capacitor structures are exposed at a first edge of capacitor module.

In one or more twentieth embodiments, further to the nineteenth embodiments, forming each of the one or more trench capacitor structures comprises forming a first electrode layer in the trench, forming a dielectric layer on the first electrode layer, forming a second electrode layer on the dielectric layer, planarizing the first electrode layer, the dielectric layer, and the second electrode layer to form a capacitor structure layer coplanar with the surface of the substrate, wherein one of the adhesive layers is directly on the capacitor structure layer.

In one or more twenty-first embodiments, further to the nineteenth or twentieth embodiments, the method further comprises inserting the capacitor module into an opening extending at least partially through an organic substrate, and securing the capacitor module to the organic substrate by a polymer material that contacts one or more exposed trench capacitor structures.

In one or more twenty-second embodiments, further to the nineteenth through twenty-first embodiments, the method further comprises contacting the electrodes of the trench capacitor structures with a plurality of metallization features, at least one of the metallization features extending over the organic substrate.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
one or more first capacitor structures embedded within corresponding first openings that extend along a length of a first surface of a first substrate, the first surface opposite a second surface of the first substrate, wherein each of the first capacitor structures comprises a capacitor surface substantially coplanar with the first surface of the first substrate;
an insulator layer on the first surface of the first substrate and on each capacitor surface, wherein first electrodes and second electrodes of the first capacitor structures are exposed at an edge of the first substrate extending between the first surface and the second surface of the first substrate; and
one or more second capacitor structures embedded within corresponding second openings that extend along a length of a first surface of a second substrate, the first surface opposite a second surface of the second substrate, wherein the first or second surface of the second substrate is on the insulator layer.

2. The apparatus of claim 1, wherein each of the capacitor surfaces comprises a region of each of the first electrode, the second electrode, and a dielectric material between the first electrode and the second electrode.

3. The apparatus of claim 1, wherein the second surface of the second substrate is on the insulator layer, the apparatus further comprising:
a second insulator layer on the first surface of the second substrate and on the second capacitor structures; and
one or more third capacitor structures embedded within corresponding third openings that extend along a length of a first surface of a third substrate, the first surface opposite a second surface of the second substrate, wherein the second surface of the third substrate is on the second insulator layer.

4. The apparatus of claim 1, wherein the edge of the first substrate is a first edge, and wherein a portion of the first substrate is between each of the first capacitor structures and a second edge of the first substrate opposite the first edge of the first substrate.

5. The apparatus of claim 1, wherein the insulator layer comprises a polymer material.

6. The apparatus of claim 1, wherein the first substrate and the second substrate each comprise a layer of glass that is rectangular in shape along the first surface of the first substrate and the first surface of the second substrate.

7. The apparatus of claim 1, wherein the first capacitor structures, first substrate, insulator layer, second capacitor structures, and second substrate comprise a capacitor module, the capacitor module extending at least partially through a thickness of an organic substrate orthogonal to a top surface of the organic substrate, wherein the first surface of the first substrate is substantially orthogonal to the top surface of the organic substrate.

8. The apparatus of claim 7, wherein the thickness of the organic substrate is not less than 1 mm, and wherein a length of the first capacitor structures extending along the thickness is not less than 0.75 mm.

9. The apparatus of claim 7, further comprising:
a first contact coupled to one of the first electrodes at the edge;
a second contact coupled to one of the second electrodes at the edge;
a metallization coupled to the first contact and extending over the organic substrate; and
an integrated circuit die coupled to the metallization.

10. An apparatus, comprising:
one or more capacitor structures embedded within corresponding openings in a first surface of an inorganic substrate, the first surface opposite a second surface of the inorganic substrate;
an organic substrate, wherein the inorganic substrate extends at least partially through a thickness of the organic substrate orthogonal to a top surface of the organic substrate, such that the first surface of the inorganic substrate is orthogonal to the top surface of the organic substrate;
a polymer material on the first surface of the inorganic substrate and the capacitor structures; and
first and second contacts coupled to first and second electrodes of one of the capacitor structures at an edge of the inorganic substrate extending from the first surface of the inorganic substrate to the second surface of the inorganic substrate.

11. The apparatus of claim 10, wherein the polymer material is on a second surface of the inorganic substrate opposite the first surface of the inorganic substrate and on a sidewall of the organic substrate.

12. The apparatus of claim 10, further comprising:
one or more second capacitor structures embedded within corresponding openings in a first surface of a second inorganic substrate, wherein the polymer material is on the first surface of the second inorganic substrate or on a second surface of the second inorganic substrate opposite the first surface of the second inorganic substrate.

13. The apparatus of claim 12, wherein the polymer material is an adhesive epoxy, the apparatus further comprising:
a mold material on a second surface of the inorganic substrate opposite the first surface of the inorganic substrate and on a sidewall of the organic substrate.

14. The apparatus of claim 10, wherein the thickness of the organic substrate is not less than 1 mm, and wherein a length of the capacitor structures extending along the thickness is not less than 0.75 mm.

15. The apparatus of claim 10, wherein the openings in the first surface of the inorganic substrate have a cross-sectional shape orthogonal to the first surface, the cross-sectional shape comprising one of a cross shape, a T-shape, a partial oval shape, or a diagonal line.

16. The apparatus of claim 10, further comprising:
an integrated circuit die coupled to one of the capacitor structures.

17. A method, comprising:
forming one or more trench capacitor structures embedded within corresponding openings that extend along a length of a surface of a substrate;
segmenting the substrate and the one or more trench capacitor structures to form a first capacitor sub-module comprising a portion of the substrate and portions of the trench capacitor structures; and
stacking a plurality of capacitor sub-modules including the first capacitor sub-module via one or more adhesive layers between surfaces of substrates of the capacitor sub-modules to form a capacitor module, wherein electrodes of the trench capacitor structures are exposed at a first edge of capacitor module.

18. The method of claim 17, wherein forming each of the one or more trench capacitor structures comprises:
forming a first electrode layer in the trench;
forming a dielectric layer on the first electrode layer;
forming a second electrode layer on the dielectric layer; and
planarizing the first electrode layer, the dielectric layer, and the second electrode layer to form a capacitor structure layer coplanar with the surface of the substrate, wherein one of the adhesive layers is directly on the capacitor structure layer.

19. The method of claim 17, further comprising:
inserting the capacitor module into an opening extending at least partially through an organic substrate; and
securing the capacitor module to the organic substrate by a polymer material that contacts one or more exposed trench capacitor structures.

20. The method of claim 19, further comprising:
contacting the electrodes of the trench capacitor structures with a plurality of metallization features, at least one of the metallization features extending over the organic substrate.
